(19) United States
(12) Patent Application Publication
(10) Pub. No.: US 2012/0235710 A1
(43) Pub. Date: Sep. 20, 2012

(54) Circuit Arrangement with a MOSFET and an IGBT

(75) Inventors: Werner Roessler, Neufahm (DE); Gerald Deboy, Klagenfurt (AT)

(73) Assignee: Infineon Technologies AG, Neubiberg (DE)

(21) Appl. No.: 13/048,471

(22) Filed: Mar. 15, 2011

(51) Int. Cl. H03L 5/00

(52) U.S. Cl. 327/109

(57) ABSTRACT

A circuit includes at least one FET and at least one IGBT that have their load paths connected in parallel. A voltage limiting circuit is coupled to a gate terminal of the at least one IGBT.

### TECHNICAL FIELD

Embodiments of the present invention relate to a circuit arrangement for switching an electrical current between a voltage source and an electrical load, in particular, for switching high currents.

### BACKGROUND

In numerous applications, like in drive trains with a converter-controlled electric machine (the load), a current between an energy source, such as an accumulator or a battery, and the load needs to be controlled by a switch. This type of switch is commonly referred to as a main switch or a main switching module. It is commonly known to implement a main switching module as a relay, which is an electromagnetically operated mechanical switch.

There are some requirements for main switching modules, particularly when applied in power circuits: (a) while in normal operating conditions, a main switching module is expected to provide low-loss operation, even at high currents; (b) a main switching module must allow for safe current interruption, i.e., safe overload disconnection or short circuit disconnection.

Relays, irrespective of whether they are applied in low-power or high-power applications, have several drawbacks. Relays, as being electromechanical switches, include a moving portion having an inherent inertia. This inherent inertia causes a delay between the time when a switching command is applied to the relays and the time when the relays actually switches. When a short-circuit occurs in the load, a significant increase of a short-circuit current may occur during a delay time between an instant when the short-circuit is detected and a switching command is generated and the instant when the relays switches. However, there are applications in which a delayed interruption of the short-circuit current may be hazardous.

Further, an electric arc may be generated when a relay is switched off. Thus, additional measures need to be taken in order to make a relays electric-arc save. However, these additional measures make those relays expensive, heavy, and considerably bulky.

There is, therefore, a need to provide a circuit arrangement that is capable of switching an electrical current between a voltage source and an electrical load, that switches rapidly, and that can be implemented at low costs.

### SUMMARY OF THE INVENTION

One embodiment relates to a circuit arrangement that includes an input terminal and an output terminal, at least one FET with a gate terminal and a drain-source path, with the drain-source path being connected between the input terminal and the output terminal, and at least one IGBT with a gate terminal and a collector-emitter path, with the collector-emitter path being connected between the input terminal and the output terminal. A voltage limiting circuit is connected to the gate terminal of the at least one IGBT and is configured to drive the at least one IGBT in an on-state when a voltage across the collector emitter path reaches a voltage limiting threshold. The circuit arrangement further includes a control circuit having a first drive output coupled to the gate terminal of the at least one FET.

### BRIEF DESCRIPTION OF THE DRAWINGS

Examples will now be explained with reference to the drawings. The drawings serve to illustrate the basic principle, so that only aspects necessary for understanding the basic principle are illustrated. The drawings are not to scale. In the drawings the same reference characters denote like features.

FIG. 1 illustrates a first embodiment of a circuit arrangement with at least one FET and at least one IGBT connected between an input terminal and an output terminal, and with a control circuit;

FIG. 2 illustrates an embodiment with a plurality of FETs connected in parallel;

FIG. 3 illustrates an embodiment with a plurality of IGBTs connected in parallel;

FIG. 4 illustrates an embodiment of a voltage limiting circuit of the IGBT;

FIG. 5 illustrates a second embodiment of the circuit arrangement;

FIG. 6 illustrates a third embodiment of the circuit arrangement;

FIG. 7 illustrates timing diagrams of first and second drive signals of the control circuit of FIG. 5 in a drive method according to a first embodiment; and

FIG. 8 illustrates timing diagrams of first and second drive signals of the control circuit of FIG. 5 in a drive method according to a second embodiment.

### DETAILED DESCRIPTION OF ILLUSTRATIVE EMBODIMENTS

In the following, embodiments of the circuit arrangement will be described in a specific context, namely in the context of a circuit arrangement that acts as a main switch and can be connected between a voltage source, such as a battery, and a load, such as an electric motor. Those main switches are, for example, used in industrial applications or in automotive applications, such as electric vehicles or hybrid vehicles. However, the circuit arrangement is not restricted to be used as a main switch, but can be used in every application in which an electrical current between a voltage source and an electrical load is to be switched.

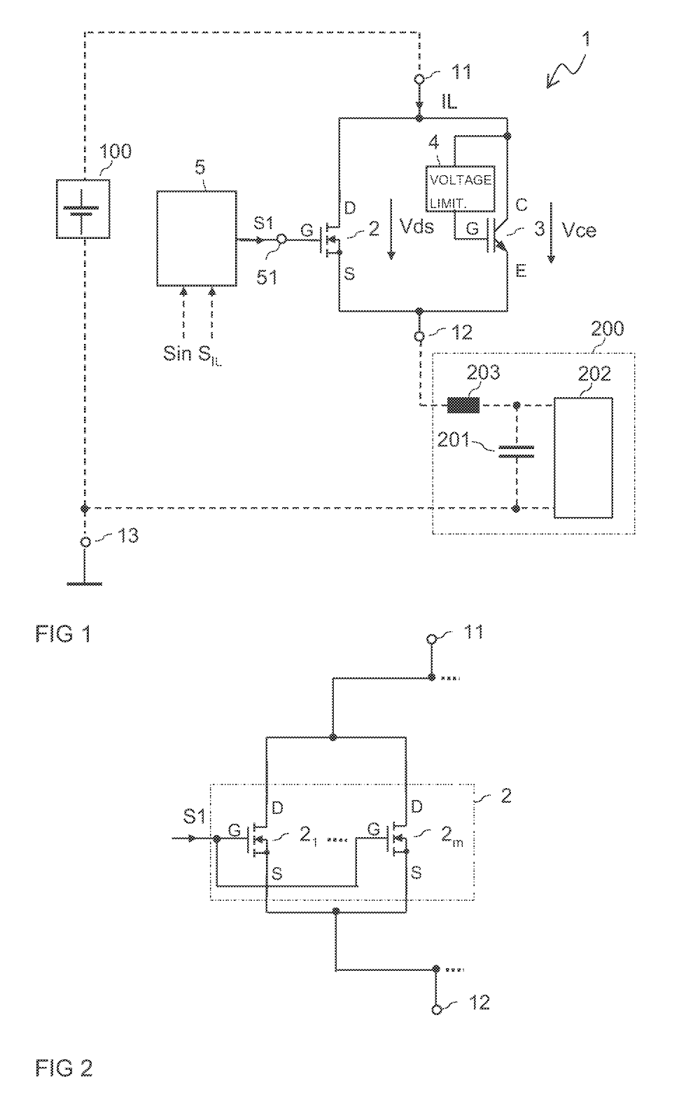

FIG. 1 illustrates a first embodiment of a circuit arrangement that is configured to switch an electrical current between a voltage source and a load. The circuit arrangement includes an input terminal 11 and an output terminal 12, at least one FET (Field-Effect Transistor) 2, at least one IGBT (Insulated-Gate Bipolar Transistor) 3, a voltage limiting circuit 4 and a control circuit 5. The at least one FET 2 includes a gate terminal G, a drain terminal D, a source terminal S, and a drain-source path D-S, which is also referred to as load path, between the drain and the source terminals D, S. The at least one IGBT 3 includes a gate terminal G, a collector terminal C, an emitter terminal E, and a collector-emitter path C-E, which is also referred to as load path, between the collector and emitter terminals C, E.

In FIG. 1 only one FET 2 and only one IGBT 3 is shown. However, this is only one example. Instead of only one FET 2 a plurality of two or more FETs can be provided that have their drain-source paths D-S connected in parallel and that have their gate terminals G connected with each other can be used. FIG. 2 illustrates an embodiment in which instead of a single MOSFET a FET arrangement 2 with a plurality of individual FETs 2₁, 2ₘ is connected between the input terminal 11 and the output terminal 12. The individual FETs 2₁, 2ₘ have their drain-source paths connected in parallel and have their gate terminals G connected with each other, so that the FETs 2₁, 2ₘ can be driven by a common drive signal. In the following, unless stated otherwise, “FET 2” means a single FET or a FET arrangement with a plurality of m FETs connected in parallel. In this connection, “drain terminal” means a drain terminal of a single FET or a common drain terminal of the plurality of FETs, “source terminal” means a source terminal of a single FET or a common source terminal of the plurality of FETs, and “gate terminal” means a gate terminal of a single FET or a common gate terminal of the plurality of FETs.

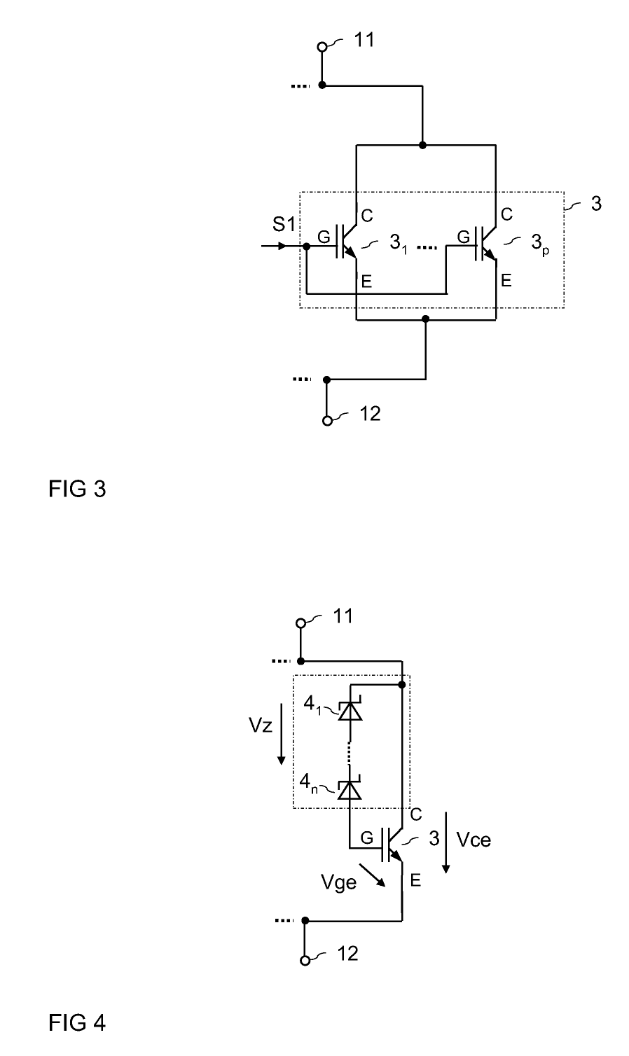

Instead of only one IGBT 3 a plurality of two or more IGBTs can be provided that have their collector-emitter paths C-E connected in parallel and that have their gate terminals G connected with each other can be used. FIG. 3 illustrates an embodiment of an IGBT arrangement 3 with a plurality of IGBTs 3₁, 3ₚ that have their collector-emitter paths connected in parallel. These IGBTs have their gate terminals connected with each other, so that these IGBTs can be driven using a common drive signal. In the following, unless stated otherwise, “IGBT 3” means a single IGBT or an IGBT arrangement with a plurality of p IGBTs connected in parallel. In this connection, “collector terminal” means a collector terminal of a single IGBT or a common collector terminal of the plurality of IGBTs, “emitter terminal” means a emitter terminal of a single IGBT or a common emitter terminal of the plurality of IGBTs, and “gate terminal” means a gate terminal of a single IGBT or a common gate terminal of the plurality of IGBTs.

Referring to FIG. 1, the drain-source path D-S of the FET 2 is connected between the input terminal 11, 12, and the collector-emitter terminal C-E of the IGBT 3 is connected between the input terminal 11 and the output terminal 12, so that the drain-source path of the FET 2 and the collector-emitter-path of the IGBT 3 are connected in parallel.

In the embodiment illustrated in FIG. 1, the FET 2 is an n-type enhancement FET that has its drain terminal D coupled to the input terminal 11, and that has its source terminal S coupled to the output terminal 12. However, implementing the FET 2 as an n-type enhancement MOSFET is only an example. Any other type of MOSFET, such as a p-type enhancement MOSFET, an n-type depletion MOSFET or a p-type depletion MOSFET, or even a junction FET (JFET) may be used as well. FET 2 may be implemented as a silicon device, or may be implemented using other semiconductor materials, such as silicon carbide (SiC), gallium arsenide (GaAs), or gallium nitride (GaN). In the following, only for illustration purposes it will be assumed that FET 2 is a MOSFET.

The voltage limiting circuit 4 is coupled to the gate terminal G of the IGBT 3. The voltage limiting circuit 4 is configured to drive IGBT 3 in an on-state when a voltage Vice across the collector-emitter path C-E reaches a voltage limiting threshold. Those types of voltage limiting circuits are commonly known. For illustration purposes, one possible embodiment of a voltage limiting circuit is illustrated in FIG. 4.

The voltage limiting circuit 4 of FIG. 4 is connected between the collector terminal C and the gate terminal G of the IGBT 3. The voltage limiting circuit 4 includes a series circuit with a plurality of Zener diodes 4₁, 4ₙ. Each of these Zener diodes 4₁, 4ₙ has a Zener voltage, which is the voltage to be applied in the reverse direction of the Zener diode at which the Zener diode starts to conduct a current in its reverse direction. Vz denotes the overall Zener voltage of the series circuit with the plurality of the Zener diodes 4₁, 4ₙ. This overall Zener voltage Vz is the sum of the Zener voltages of the individual Zener diodes 4₁, 4ₙ. This voltage limiting circuit 4 switches the IGBT 3 on when the collector-emitter voltage Vce reaches a voltage value which corresponds to the Zener voltage Vz plus the threshold voltage Vth of the IGBT 3. The threshold voltage Vth of the IGBT 3 is the gate-emitter voltage Vge at which the IGBT 3 starts to conduct a current between the collector terminal C and the emitter terminal E. Typically, the threshold voltage Vth is between about 0.7V and 1.0V in a silicon device. The specific voltage value of the collector-emitter voltage Vce at which the voltage limiting circuit 4 starts to drive the IGBT 3 in its on-state is dependent on the number of Zener diodes 4₁, 4ₙ connected in series and is dependent on the Zener voltages of the individual diodes 4₁, 4ₙ.

The voltage limiting circuit 4 switches the IGBT 3 on only to such an extent that the collector-emitter voltage Vce is limited to a threshold value defined by the Zener voltage Vz and the threshold voltage Vth of the IGBT 3. In this operation mode the IGBT 3 usually has an on-resistance that is relatively high compared to an on-resistance that occurs when a gate-emitter voltage Vge is applied that is significantly higher than the threshold voltage Vth, such as a gate-emitter voltage of between 8V and 15V. The on-state of the IGBT 3 caused by the voltage limiting circuit 4 will, therefore, be referred to as high-resistance on-state in the following. In this high-resistance on-state the IGBT 3, due to its high on-resistance, is capable of dissipating electrical power. This will be explained in more detail herein further below.

It should be noted that implementing the voltage limiting circuit 4 with a plurality of Zener diodes is only an example. Any other type of voltage limiting circuit that is configured to limit the voltage across the collector-emitter path C-E of the IGBT 3 to a given threshold value may be used as well.

Referring to FIG. 1, the circuit arrangement further includes a control circuit 5 with a first drive terminal 51 coupled to the gate terminal G of the FET 2. The control circuit 5 provides a first drive signal S1 at the first drive terminal 51 and is configured to switch FET 2 on and off. According to one embodiment, the first drive signal S1 can assume two different signal levels, namely an on-level and an off-level, wherein the FET 2 is switched on when the first drive signal S1 assumes an on-level, and is switched off when the first drive signal S1 assumes an off-level. The absolute signal level of the on-level and the off-level is dependent on the type of FET. In an n-type MOSFET the on-level of the first drive signal S1 is a positive signal level relative to the potential at the source terminal S, and the off-level is zero or a negative signal level relative to the potential at the source terminal S.

The control circuit 5 can be configured to switch the MOSFET 2 on and off dependent on an input signal Sin (illustrated in dashed lines) received at an input terminal of the control terminal 5. Additionally or alternatively the control circuit 5 can be configured to switch the MOSFET off dependent on a load current IL flowing through the circuit arrangement between the input terminal 11 and the output terminal 12. For this, the control circuit 5 receives a current measurement signal S_{IL} that is representative of the load current IL. According to one embodiment, the control circuit 5 is configured to switch the MOSFET 2 off, when the load current IL reaches a current threshold. The current measurement signal S_{IL} can be provided by a conventional current measurement circuit (not illustrated in FIG. 1).

Referring to FIG. 1, the circuit arrangement with the FET 2 and the IGBT 3 can be used as a main switch for switching a load current IL between a voltage source 100 and a load circuit 200. In this case, the voltage source 100 is connected between the input terminal 11 and a terminal 13 for a reference potential, such as ground GND. The load circuit 200 is connected between the output terminal 12 and the terminal 13 for the reference potential. The voltage source 100 is, for example, a DC voltage source, providing a DC input voltage Vin. According to one embodiment, the voltage source 100 is a battery or a battery stack. The input voltage Vin is, for example, in the range of several 100V, such as between 300V and 500V, and in particular about 400V.

The load circuit 200 can be a conventional electrical load to be supplied with a DC voltage. In the application scenario illustrated in FIG. 1, the load circuit 200 receives the input voltage Vin via the circuit arrangement 1 when the circuit arrangement 1 is in its on-state. The circuit arrangement 1 is in its on-state when at least the FET 2 is switched on, i.e. when FET 2 is in its on-state. The load circuit 200 of FIG. 1 includes a capacitor 201 coupled between the output terminal 12 and the reference terminal 13, and a load 202 connected in parallel with the capacitor 201. Capacitor 201 acts as a buffer. This type of capacitor is also known as DC link capacitor. The load 202 is, for example, an electrical motor, such as a motor used in industrial applications, or in automotive applications, such as electrical cars or hybrid cars. In FIG. 1, inductance 203 represents a line inductance of a connection line arranged between the switching arrangement 1 and the load circuit 200. In particular in cars those connection lines may have a significant length, resulting in a significant line inductance, such as line inductances of several 10 μH up to several 100 μH.

When the circuit arrangement 1 is in its on-state electrical energy is inductively stored in the line inductance 203. The energy stored in the line inductance 203 is dependent on the inductance value of the line inductance 203 and on the load current IL, wherein the energy increases when the inductance value of the line inductance 203 increases or when the load current IL increases. The inductance value of the line inductance 203 increases, for example, when a length of the connection line is increased. The load current IL may, for example, increase, when a short-circuit occurs in the load circuit 200.

When the circuit arrangement 1 is switched off, the electrical energy stored in the line inductance 203 has to be dissipated, which means that the electrical energy has to be transformed into thermal energy. The circuit arrangement 1 of FIG. 1 is switched off when the MOSFET 2 is switched off.

In the circuit arrangement of FIG. 1 the IGBT 3 serves to dissipate the electrical energy stored in the line inductance 203. When energy has been stored in the line inductance 203 during the on-state of the circuit arrangement 1, and when the circuit arrangement 1 enters its off-state by switching FET 2 off, the line inductance 203 causes the electrical potential at the output terminal 12 to decrease until the collector-emitter voltage Vce of the IGBT 3 reaches the voltage limiting threshold defined by the voltage limiting circuit 4. When the collector-emitter voltage Vce reaches this voltage limiting threshold the voltage limiting circuit 4 drives the IGBT 3 into its high-resistance on-state. In this high-resistance on-state at least a part of the electrical energy stored in the line inductance 203 is dissipated in the IGBT 3 until the collector-emitter voltage Vce drops to below the voltage limiting threshold.

The FET 2 has a voltage blocking capability. The voltage blocking capability corresponds to the maximum drain-source voltage Vds that can be applied across the drain-source path of the FET 2 without causing an avalanche breakthrough. According to one embodiment, the voltage limiting threshold defined by the voltage limiting circuit 4 is below the voltage blocking capability of the MOSFET 2. This helps to prevent an avalanche breakthrough of the MOSFET 2 when the circuit arrangement 1 is switched off. According to one embodiment, the input voltage Vin is about 400V, the voltage blocking capability of the MOSFET 2 is about 650V, and the voltage limiting threshold is about 600V. The load current IL is, for example, about 100 A when the load circuit 200 is in a normal operation mode. However, the load current IL may increase up to several 100 A when a short circuit occurs in the load circuit 200. The voltage blocking capability of the IGBT 3 is, for example, about 1200V.

Referring to what has been explained hereinbefore, a plurality of two or more MOSFET 2 can be connected in parallel and commonly driven by the first drive signal S1 in order to reduce the on-resistance. The on-resistance is the ohmic resistance that occurs when the MOSFET 2 is switched on. According to one embodiment between m=2 and m=5, in particular m=3, MOSFETs are connected in parallel, and between p=5 and p=10 IGBTs are connected in parallel. The number of IGBTs is, in particular, higher than the number of MOSFETs 2, in order to ensure that the electrical power stored in the line inductance 203 is safely dissipated in the IGBTs at the time of switching off.

There are MOSFETs available that have a lower on-resistance than IGBTs. There are power MOSFETs with a voltage blocking capability of 650V available that have an on-resistance of 9 mΩ or even below. These MOSFETs are, for example, implemented as superjunction devices. Those types of devices are commonly known. If, for example, three of those MOSFETs are connected in parallel, (resulting in an overall on-resistance of 3 mΩ) the power losses in the MOSFET arrangement are only about P_{ON}=30 W at a load current IL of 100 A (P_{ON}=R_{ON}·IL², where R_{ON} denotes the overall on-resistance). The power losses occurring in an IGBT arrangement would be significantly higher, such as about 100 W. The reason is that the voltage across the collector-emitter path of an IGBT in the on-state can never fall below about 1V. This is because of the specific design of IGBTs; IGBTs internally have a PN junction in their collector-emitter path, wherein the voltage drop only across this PN junction is about 0.7V when the IGBT is in its on-state.

In the circuit arrangement of FIG. 1 the FET 2 conducts the load current IL when the circuit arrangement 1 is in its on-state. In this operating state the IGBT 3 is switched off, because the collector-emitter voltage Vice is below the voltage limiting threshold. In this circuit arrangement the IGBT 3 only serves to dissipate the electrical power stored in the line inductance 203 when the circuit arrangement 1 is switched off. Modern MOSFETs, such as the MOSFETs explained herein before having a low on-resistance, are not capable to dissipate electrical power.

Unlike conventional relays, the FET 2 can be switched off very fast, such as with a switching delay of 200 μs or less. The switching delay is a time difference between a time at which the first drive signal assumes an off-level and the time at which MOSFET 2 actually switches off. A small switching delay is, in particular, advantageous when the FET 2 is to be switched off upon detection of a short circuit. When a short circuit occurs the load current IL can rapidly increase. The electrical power stored in the line inductance 203 that is to be dissipated in the IGBT 3 increases when the load current IL increases. Thus, the power to be dissipated in the IGBT 3 is lower when there is only a small switching delay of the FET 2. A short circuit of the load is, for example, detected when the load current IL reaches a current threshold which is higher than the load current IL in the normal operation mode. According to one embodiment, the current threshold is selected to be between 1.3 times and 2 times of the load current in the normal operation mode.

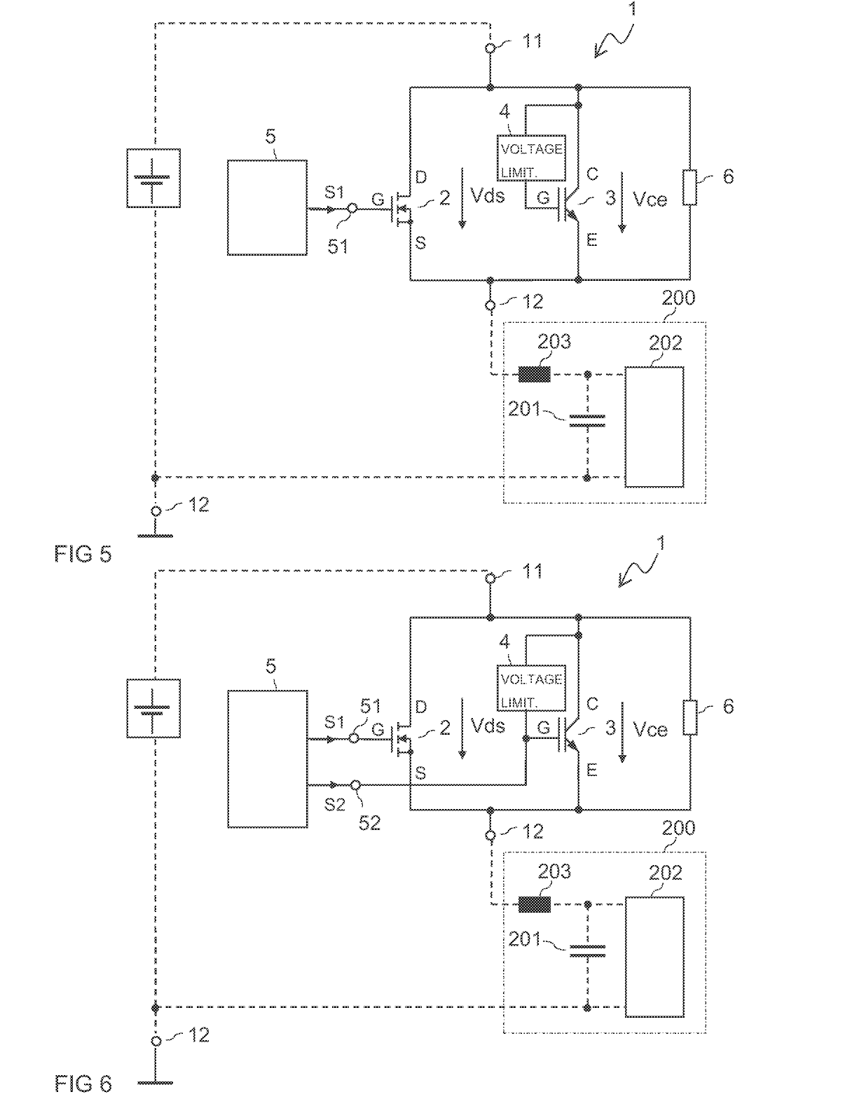

FIG. 5 illustrates a further embodiment of the circuit arrangement 1. In this embodiment, a resistor 6 is connected in parallel with the drain-source path of the FET 2 and the collector-emitter path of the IGBT 3 and between the input terminal 11 and the output terminal 12. When the load circuit includes a DC link capacitor, such as DC link capacitor 201 illustrated in FIG. 5, the DC link capacitor is charged via the resistor 6 when the input voltage Vin is applied at the input terminal 11 before the MOSFET 2 is switched on. By virtue of the resistor 6 a voltage across the DC link capacitor 201 approximately equals the input voltage Vin before the MOSFET 2 is switched on. Otherwise, the DC link capacitor 201 would have to be charged via the FET 2 when the FET 2 is switched on for the first time. However, this could result in a load current IL that is above the short-circuit current threshold, causing the control circuit 5 to switch FET 2 off before the DC link capacitor 201 is charged. A resistance value of the resistor 6 is selected such that a current which can flow via the resistor 6 is too low in order to drive the load 202. According to one embodiment, resistor 6 is a PTC (positive thermal coefficient) resistor.

FIG. 6 illustrates a further embodiment of the circuit arrangement 1. In this embodiment, the control circuit 5 has a second drive terminal 52 coupled to the gate terminal of the IGBT 3. The control circuit 5 provides a second drive signal S2 at the second drive terminal 52. According to one embodiment, the second drive signal S2 can assume two different signal levels, namely an on-level that switches the IGBT 3 on, and an off-level that switches the IGBT 3 off. The on-level is selected such that it drives IGBT 3 on in a low-resistance on-state. The on-level is significantly higher than the threshold voltage Vth of the IGBT 3. According to one embodiment, the on-level corresponds to a voltage of between 5V and 15V between the gate terminal G and the emitter terminal E of the IGBT 3.

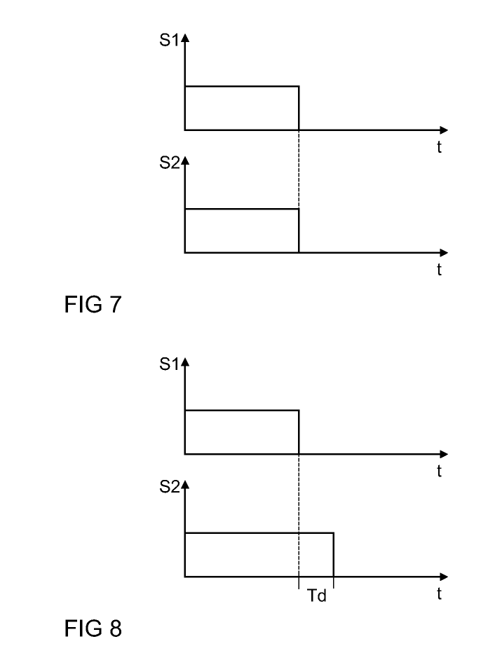

In the circuit arrangement of FIG. 6 the IGBT 3 does not only serve to dissipate electrical power stored in the line inductance 203, but may also contribute to conducting the load current IL. According to one embodiment, the control circuit 5 is configured to switch both, the MOSFET 2 and the IGBT 3, on, when the circuit arrangement 1 is in its on-state. In this case, a part of the load current IL flows through the FET 2, while another part of the load current IL flows through the IGBT 3. When the circuit arrangement 1 is to be switched off, either because the load 200 is to be switched off or because a short circuit has been detected, there are two possible scenarios which will be explained with reference to FIGS. 7 and 8. FIGS. 7 and 8 show timing diagrams of the first and second drive signals S1, S2 generated by the control circuit 5. For illustration purposes, a high-signal level represents an on-level and a low signal represents an off-level of the corresponding drive signal S1, S2.

Referring to FIG. 7, the control circuit 5, according to a first embodiment, is configured to switch off the FET 2 and the IGBT 3 at the same time. This is illustrated in FIG. 7 by the first and second drive signals S1, S2 having falling edges at the same time. According to a further embodiment, illustrated in FIG. 8, the control circuit 5 is configured to switch off MOSFET 2 first, and to switch off the IGBT 3 after a delay time Td after the FET 2 has been switched off. This is illustrated in FIG. 8 by the presence of a delay time between the falling edges of the first drive signal S1 and the second drive signal S2. In this switching scenario the load current IL completely flows through the IGBT 3 during the delay time Td before the IGBT 3 is also switched off. This has the effect that the complete load current is homogeneously distributed in the IGBT 3 before the IGBT 3 is switched off. When the MOSFET 2 and the IGBT 3 are switched off at the same time, there is, at first, a rapid increase of the current through the IGBT.

Although various exemplary embodiments of the invention have been disclosed, it will be apparent to those skilled in the art that various changes and modifications can be made which will achieve some of the advantages of the invention without departing from the spirit and scope of the invention. It will be obvious to those reasonably skilled in the art that other components performing the same functions may be suitably substituted. It should be mentioned that features explained with reference to a specific figure may be combined with features of other figures, even in those cases in which this has not explicitly been mentioned. Further, the methods of the invention may be achieved in either all software implementations, using the appropriate processor instructions, or in hybrid implementations that utilize a combination of hardware logic and software logic to achieve the same results. Such modifications to the inventive concept are intended to be covered by the appended claims.

What is claimed is:

1. A circuit, comprising:
an input terminal and an output terminal;
at least one FET having a gate terminal and a drain-source path, the drain-source path coupled between the input terminal and the output terminal;
at least one IGBT having a gate terminal and a collector-emitter path, the collector-emitter path coupled between the input terminal and the output terminal;
a voltage limiting circuit coupled to the gate terminal of the at least one IGBT and configured to drive the at least one IGBT in an on-state when a voltage across the collector-emitter path reaches a threshold voltage; and
a control circuit having a first drive output coupled to the gate terminal of the at least one FET.

2. The circuit of claim 1, further comprising:
a resistor coupled between the input terminal and the output terminal.

3. The circuit of claim 2, wherein the resistor is a PTC resistor.

4. The circuit of claim 1, wherein the at least one FET has a voltage blocking capability, and wherein the threshold voltage is below the voltage blocking capability.

5. The circuit of claim 1, wherein the voltage limiting circuit comprises:
at least one voltage limiting element connected between a drain terminal and the gate terminal of the at least one IGBT.

6. The circuit of claim 5, wherein the voltage limiting circuit is a Zener diode.

7. The circuit of claim 6, wherein a plurality of Zener diodes is connected in series between the drain terminal and the gate terminal of the at least one IGBT.

8. The circuit of claim 1, wherein the at least one IGBT has only the voltage limiting circuit connected to its gate terminal.

9. The circuit of claim 1, wherein the control circuit further comprises a second drive output coupled to the gate terminal of the at least one IGBT.

10. The circuit of claim 9, wherein the circuit is configured to assume
an on-state in which the control circuit generates an on-level of a first drive signal at the first drive output and an on-level of a second drive signal at a second drive output, or
an off-state in which the control circuit generates an off-level of the first drive signal at the first drive output and an off-level of the second drive signal at the second drive output.

11. The circuit of claim 10, wherein the control circuit at a beginning of the off-state is configured to generate the off-levels of the first and second drive signals at the same time.

12. The circuit of claim 10, wherein the control circuit at a beginning of the off-state is configured to generate the off-level of the second drive signal after the off-level of the first drive signal.

13. The circuit of claim 1, wherein the at least one FET comprises a plurality of FETs having their drain-sources paths connected in parallel and having their gate terminals connected with each other.

14. The circuit of claim 1, wherein the at least one IGBT comprises a plurality of IGBTs having their collector-emitter paths connected in parallel and having their gate terminals connected with each other.

15. The circuit of claim 1, wherein the at least one FET is implemented as a MOSFET.
